(19) United States
(12) Patent Application Publication
(10) Pub. No.: US 2026/0113987 A1
(43) Pub. Date: Apr. 23, 2026

(54) THIN-FILM TRANSISTOR AND MANUFACTURING METHOD THEREFOR

(71) Applicant: JUSUNG ENGINEERING CO., LTD., Gwangju-si, Gyeonggi-do (KR)

(72) Inventors: Il Houng PARK, Yongin-si, Gyeonggi-do (KR); Chul Joo HWANG, Yongin-si, Gyeonggi-do (KR)

(21) Appl. No.: 19/116,994

(22) PCT Filed: Oct. 12, 2023
(86) PCT No.: PCT/KR2023/015700

§ 371 Date: Mar. 28, 2025

(30) Foreign Application Priority Data
Oct. 20, 2022 (KR) 10-2022-0135935

(51) Int. Cl. H10D 30/67; H10D 30/01

(52) U.S. Cl. CPC H10D 30/6737; H10D 30/031; H10D 30/6755

(57) ABSTRACT

The present inventive concept relates to a thin-film transistor and a manufacturing method therefor. The thin film transistor
comprises: a gate electrode; an active layer spaced apart from the gate electrode; a source electrode provided on one side of the
active layer; a drain electrode provided on the other side of the active layer; and a contact layer provided in at least one between the
active layer and the source electrode and between the active layer and the drain electrode. The contact layer includes a first metal
oxide of at least one selected from Zn, In, and Ga.

### TECHNICAL FIELD

The present inventive concept relates to a thin film transistor and a method of manufacturing the same, more particularly, to an oxide thin film transistor and a method of manufacturing the same.

### BACKGROUND ART

A thin film transistor is used as a circuit element for independently driving each pixel in semiconductor devices, liquid crystal displays (LCDs), and organic EL (Electro Luminescence) displays.

Such a thin film transistor includes a gate electrode, an active layer used as a channel, a source electrode, and a drain electrode. In this case, when a metal oxide is used as a material for the active layer, it is referred to as an oxide thin film transistor.

In the process of manufacturing an oxide thin film transistor, the active layer is exposed to an etching gas during an etching process for patterning. When the active layer is exposed to the etching gas, the exposed surface is damaged by the etching gas and oxygen contained therein is lost. When oxygen deficiency occurs in the active layer, the electrical conductivity of the active layer increases and the active layer becomes a conductor, resulting in a short circuit that cannot stably drive the thin film transistor.

### DISCLOSURE

### Technical Problem

The present inventive concept is devised to solve the above-described problem and is for providing a thin film transistor capable of improving stability by preventing oxygen deficiency in an active layer and a method of manufacturing the same.

### Technical Solution

To accomplish the above-described objects, an embodiment of the present inventive concept provides a thin film transistor comprising: a gate electrode; an active layer spaced apart from the gate electrode; a source electrode provided on one side of the active layer; a drain electrode provided on the other side of the active layer; and a contact layer provided at least one of an area between the active layer and the source electrode and an area between the active layer and the drain electrode, wherein the contact layer comprises a first metal oxide of at least one selected from Zn, In, and Ga.

The contact layer can include a first contact layer provided between the active layer and the source electrode, and a second contact layer provided between the active layer and the drain electrode.

The active layer can include a second metal oxide, and the second metal oxide included in the active layer and the first metal oxide included in the contact layer can be different from each other.

Metal included in the first metal oxide can be different from metal included in the second metal oxide.

A composition ratio of metal and oxygen included in the first metal oxide can be different from a composition ratio of metal and oxygen included in the second metal oxide.

Oxygen content included in the first metal oxide can be less than oxygen content included in the second metal oxide.

The contact layer can have a thickness in the range of 30 Å to 100 Å.

A pattern of the contact layer can be different from a pattern of the active layer.

The thin film transistor can further comprise an interlayer insulating layer provided between the active layer and the source electrode, and the interlayer insulating layer can be provided with a contact hole for exposing the source electrode, and the contact layer is provided in the contact hole.

The thin film transistor can further comprise a gate insulating layer provided between the gate electrode and the active layer, and the source electrode can extend from an upper surface of the contact layer to an upper surface of the gate insulating layer.

Another embodiment of the present inventive concept provides a method of manufacturing a thin film transistor comprising: forming an active layer on a substrate; forming a gate insulating film and a gate electrode on the active layer; forming an interlayer insulating layer on the gate electrode; forming a contact hole in the interlayer insulating layer to expose the active layer through the contact hole; forming a contact layer containing a first metal oxide of at least one selected from Zn, In, and Ga on an exposed upper surface of the active layer within the contact hole; and forming a source electrode or a drain electrode on the contact layer.

The interlayer insulating layer can be made of nitride, and the contact layer is formed by a selective deposition process without a patterning process.

Another embodiment of the present inventive concept provides a method of forming a thin film transistor comprising: forming a gate electrode on a substrate; forming a gate insulating film on the gate electrode; forming an active layer on the gate insulating film; forming a contact layer containing a first metal oxide of at least one selected from Zn, In, and Ga on an upper surface of the active layer; and forming a source electrode or a drain electrode on the contact layer.

The active layer can include a second metal oxide, and the second metal oxide included in the active layer and the first metal oxide included in the contact layer can be different from each other.

Metal included in the first metal oxide can be different from metal included in the second metal oxide.

A composition ratio of metal and oxygen included in the first metal oxide can be different from a composition ratio of metal and oxygen included in the second metal oxide.

Oxygen content included in the first metal oxide can be less than oxygen content included in the second metal oxide.

The contact layer can have a thickness in the range of 30 Å to 100 Å.

### Advantageous Effect

According to the present inventive concept, the following effects may be realized.

According to an embodiment of the present inventive concept, since a contact layer made of metal oxide is formed between the active layer and the source electrode and between the active layer and the drain electrode, oxygen included in the contact layer may fill a place in the active layer from which the oxygen escapes. Therefore, the oxygen included in the contact layer is diffused to the place in the active layer where the oxygen escapes, so that the active layer can be prevented from becoming a conductor.

### DESCRIPTION OF DRAWINGS

FIG. 1 is a schematic cross-sectional view of a thin film transistor according to an embodiment of the present inventive concept.

FIG. 2 is a schematic cross-sectional view of a thin film transistor according to another embodiment of the present inventive concept.

FIGS. 3A to 3C are cross-sectional views of a schematic manufacturing process of a thin film transistor according to an embodiment of the present inventive concept.

FIGS. 4a to 4c are cross-sectional views of a schematic manufacturing process of a thin film transistor in accordance with another embodiment of this invention.

### MODE FOR INVENTION

Advantages and features of the present inventive concept, and implementation methods thereof will be clarified through following embodiments described with reference to the accompanying drawings. The present inventive concept may, however, be embodied in different forms and should not be construed as limited to the embodiments set forth herein. Rather, these embodiments are provided so that this invention will be thorough and complete, and will fully convey the scope of the present inventive concept to those skilled in the art. Furthermore, the present inventive concept is only defined by scopes of claims.

A shape, a size, a ratio, an angle, and a number disclosed in the drawings for describing embodiments of the present inventive concept are merely an example, and thus, the present inventive concept is not limited to the illustrated details. Like reference numerals refer to like elements throughout. In the following description, when the detailed description of the relevant known technology is determined to unnecessarily obscure the important point of the present inventive concept, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a time relationship, for example, when the temporal order is described as ‘after˜’, ‘subsequent˜’, ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concept.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present inventive concept may be partially or overall coupled to or combined with each other, and may be variously inter-operated with each other and driven technically as those skilled in the art can sufficiently understand. The embodiments of the present inventive concept may be carried out independently from each other, or may be carried out together in co-dependent relationship.

Hereinafter, preferable embodiments of the present inventive concept will be described in detail with reference to the accompanying drawings.

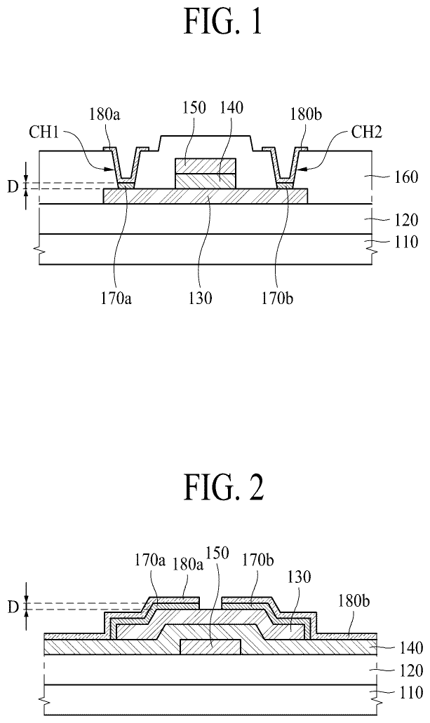

FIG. 1 is a schematic cross-sectional view of a thin film transistor according to an embodiment of the present inventive concept.

FIG. 1 relates to a thin film transistor having a top gate structure in which the gate electrode 150 is provided above the active layer 130.

As shown in FIG. 1, the thin film transistor according to an embodiment of the present inventive concept includes a substrate 110, a buffer layer 120, an active layer 130, a gate insulating layer 140, a gate electrode 150, an interlayer insulating layer 160, contact layers 170a and 170b, a source electrode 180a, and a drain electrode 180b.

The substrate 110 may be made of various materials known in the art, such as glass, plastic, or semiconductor substrates. The substrate 110 may be formed of a transparent substrate or may be formed of an opaque substrate. The substrate 110 may be formed of a reflective substrate made of a metal material such as stainless steel (SUS), titanium (Ti), molybdenum (Mo), or an alloy thereof.

The buffer layer 120 is formed on the substrate 110. Specifically, the buffer layer 120 may be formed between the substrate 110 and the active layer 130 to prevent the material contained in the substrate 110 from diffusing into the active layer 130 during the deposition process of the active layer 130. In addition, the buffer layer 120 may serve to prevent external moisture or oxygen from penetrating into the active layer 130 through the substrate 110.

The buffer layer 120 may include silicon oxide, but is not limited thereto.

The active layer 130 is patterned on the buffer layer 120.

The active layer 130 may be made of a metal oxide. The active layer 130 may be formed of a single layer of metal oxide, or may be formed of a plurality of layers of metal oxide.

The active layer 130 may include, for example, a metal oxide, for example, zinc oxide doped with impurities. The impurity may include, for example, at least one material among indium (In), gallium (Ga), and tungsten (W).

Indium (In) is a metal having a relatively small band gap, and when the active layer 130 contains indium, charge concentration can be increased and charge mobility can be improved. Gallium (Ga) is a metal having a relatively large band gap, and when the active layer 130 contains gallium, charge concentration is reduced so that device stability can be improved. Therefore, the electrical conductivity of the active layer 130 may be controlled by controlling the content of impurities contained in the metal oxide. In addition, as the ratio of oxygen in the active layer 130 made of metal oxide increases, the electrical conductivity of the active layer 130 may decrease.

The gate insulating layer 140 is patterned on the active layer 130.

The gate insulating layer 140 is formed between the active layer 130 and the gate electrode 150 to insulate between the active layer 130 and the gate electrode 150.

The gate insulating layer 140 may be formed of an inorganic insulating material such as silicon oxide (SiO₂), silicon nitride (SiNₓ), alumina (Al₂O), or zirconia (ZrO₂), but is not limited thereto.

The gate insulating layer 140 may be formed in the same pattern as the gate electrode 150, but is not limited thereto.

The gate electrode 150 is patterned on the gate insulating layer 140. The gate electrode 150 is formed to overlap the active layer 130.

The gate electrode 150 and the gate insulating layer 140 are patterned to expose a portion of the upper surface of the active layer 130.

The gate electrode 150 may be formed of at least one metal of aluminum (Al), neodymium (Nd), silver (Ag), chromium (Cr), titanium (Ti), tantalum (Ta), molybdenum (Mo), and an alloy including the same, but is not limited thereto. The gate electrode 150 may be formed of a single layer or multiple layers of the metal or alloy. For example, the gate electrode 150 may be formed of a double layer including one metal layer selected from chromium (Cr), titanium (Ti), tantalum (Ta), or molybdenum (Mo) with excellent physical and chemical properties and another metal layer selected from an aluminum (Al)-based, silver (Ag)-based or copper (Cu)-based metal layer with low specific resistance.

The interlayer insulating layer 160 is formed on the gate electrode 150 to cover the active layer 130 and the gate electrode 150. A first contact hole CH1 and a second contact hole CH2 are provided in the interlayer insulating layer 160, and a predetermined region of the active layer 130 is exposed by the first contact hole CH1 and the second contact hole CH2.

The interlayer insulating layer 160 may be formed of an inorganic insulating material such as silicon oxide (SiO₂), silicon nitride (SiNₓ), alumina (Al₂O3), or zirconia (ZrO₂), but is not limited thereto.

The source electrode 180a and the drain electrode 180b are formed on the interlayer insulating layer 160. The source electrode 180a and the drain electrode 180b are spaced apart from each other with the gate electrode 150 interposed therebetween.

The source electrode 180a and the drain electrode 180b may be formed of the same material by the same process. For example, the source electrode 180a and the drain electrode 180b may be formed of a single layer or multiple layers of an alloy including at least one metal among aluminum (Al), neodymium (Nd), silver (Ag), chromium (Cr), titanium (Ti), tantalum (Ta), and molybdenum (Mo).

The source electrode 180a is electrically connected to an upper surface of one side of the active layer 130 through the first contact hole CH1, and the drain electrode 180b is electrically connected to an upper surface of the other side of the active layer 130 through the second contact hole CH2.

The contact layers 170a and 170b include a first contact layer 170a and a second contact layer 170b. The first contact layer 170a may be provided in the first contact hole CH1, and the second contact layer 170b may be provided in the second contact hole CH2. Thus, the contact layers 170a and 170b have a different pattern from that of the active layer 130.

The first contact layer 170a is provided between the source electrode 180a and the upper surface of one side of the active layer 130 to electrically connect the source electrode 180a to the upper surface of one side of the active layer 130. Therefore, the top surface of the first contact layer 170a is in contact with the bottom surface of the source electrode 180a, and the bottom surface of the first contact layer 170a is in contact with the top surface of one side of the active layer 130.

The second contact layer 170b is provided between the drain electrode 180b and the upper surface of the other side of the active layer 130 to electrically connect the drain electrode 180b to the upper surface of the other side of the active layer 130. Thus, the upper surface of the second contact layer 170b is in contact with the lower surface of the drain electrode 180b, and the lower surface of the second contact layer 170b is in contact with the upper surface of the other side of the active layer 130.

Each of the first contact layer 170a and the second contact layer 170b may be formed of a metal oxide. Each of the first contact layer 170a and the second contact layer 170b can be formed as a single layer of metal oxide or multiple layers of metal oxide.

Specifically, each of the first contact layer 170a and the second contact layer 170b may be formed of a single layer or multiple layers of at least one metal oxide selected from Zn, In, and Ga. For example, each of the first contact layer 170a and the second contact layer 170b may be formed of a single layer or multiple layers of metal oxide selected from ZnO, InO, GaO, IZO, IGO, GZO, and IGZO.

Each of the first contact layer 170a and the second contact layer 170b may be formed of a metal oxide different from that of the active layer 130. For example, when the metal oxide for forming the active layer 130 is referred to as a first metal oxide, and the metal oxide for forming the contact layers 170a and 170b is referred to as a second metal oxide, the metal constituting the second metal oxide and the metal constituting the first metal oxide may be different from each other. In some cases, the metal constituting the second metal oxide and the metal constituting the first metal oxide may be the same, and in this case, the composition ratio of the metal and the oxygen for constituting the second metal oxide may be different from the composition ratio of the metal and the oxygen for constituting the first metal oxide. In particular, the second metal oxide may have a smaller oxygen content and a larger metal content than the first metal oxide.

The first contact layer 170a and the second contact layer 170b may serve to prevent one side and the other side of the active layer 130 exposed by the first contact hole CH1 from becoming conductive during a process.

If the source electrode 180a and the drain electrode 180b are directly formed on the active layer 130 without forming the contact layers 170a and 170b, the upper surface of the active layer 130 is exposed by an etching gas in the process of forming the first and second contact holes CH1 and CH2 in the interlayer insulating layer 160 to form the source electrode 180a and the drain electrode 180b. In this way, when the active layer 130 is exposed by the etching gas, the active layer 130 is damaged by the etching gas from the upper surface to a predetermined depth, and oxygen is lost, resulting in an oxygen deficiency state. In this way, when oxygen deficiency occurs in the active layer 130, the active layer 130 becomes a conductor due to an increase in electrical conductivity, and accordingly, a device short circuit occurs, making it impossible to stably drive the thin film transistor.

On the other hand, according to an embodiment of the present inventive concept, since contact layers 170a and 170b made of a metal oxide are formed between the active layer 130 and the source electrode 180a and between the active layer 130 and the drain electrode 180b, oxygen included in the contact layers 170a and 170b may fill a place in the active layer 130 from which oxygen escapes. Accordingly, oxygen included in the contact layers 170a and 170b is diffused to the place in the active layer 130 where oxygen escapes, thereby preventing the active layer 130 from becoming a conductor.

In this case, the contact layers 170a and 170b may be formed to have a thickness D of 30 Å to 100 Å. At this time, when the contact layers 170a and 170b are formed to have a thickness of less than 30 Å, oxygen diffusion to the active layer 130 may not be sufficient, and when the contact layers 170a and 170b are formed to have a thickness exceeding 100 Å, the process time may be excessively increased and miniaturization of the thin film transistor may be hindered.

FIG. 2 is a schematic cross-sectional view of a thin film transistor according to another embodiment of the present inventive concept.

FIG. 2 is about a thin film transistor having a bottom gate structure in which the gate electrode 150 is provided below the active layer 130.

As shown in FIG. 2, the thin film transistor according to another embodiment of the present inventive concept includes a substrate 110, a buffer layer 120, an active layer 130, a gate insulating layer 140, a gate electrode 150, contact layers 170a and 170b, a source electrode 180a, and a drain electrode 180b. Since the materials of each component are the same as those of FIG. 1 described above, repeated descriptions thereof will be omitted, and different structures will be described below.

Since the substrate 110 and the buffer layer 120 are the same as those of FIG. 1 described above, repeated descriptions thereof will be omitted. The buffer layer 120 may be omitted.

The gate electrode 150 is patterned on the buffer layer 120.

The gate insulating layer 140 is formed on the gate electrode 150. The gate insulating layer 140 may be formed on the entire surface of the substrate 110.

The active layer 130 is patterned on the gate insulating layer 140, and a portion of the active layer 130 overlaps the gate electrode 150.

The first contact layer 170a is provided on an upper surface of one side of the active layer 130 to electrically connect the source electrode 180a with the upper surface of one side of the active layer 130.

The second contact layer 170b is provided on the upper surface of the other side of the active layer 130 to electrically connect the drain electrode 180b with the upper surface of the other side of the active layer 130.

The first contact layer 170a and the second contact layer 170b may additionally supply oxygen when oxygen deficiency occurs on the upper surface of the active layer 130 due to etching gas when forming the pattern of the active layer 130, thereby preventing the active layer 130 from becoming conductive.

The source electrode 180a may extend from the first contact layer 170a to an upper surface of one side of the gate insulating layer 140, and the drain electrode 180b may extend from the second contact layer 170b to an upper surface of the other side of the gate insulating layer 140.

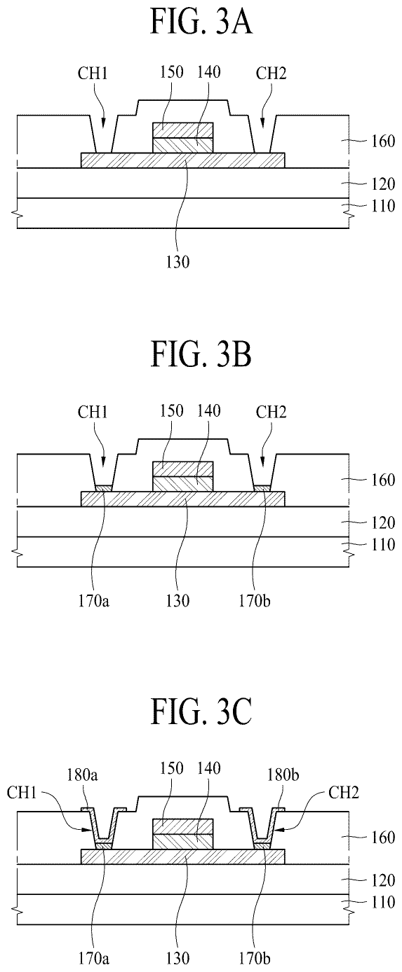

FIGS. 3A to 3C are cross-sectional views of a schematic manufacturing process of a thin film transistor according to an embodiment of the present inventive concept, and are related to a manufacturing process of the thin film transistor according to FIG. 1 described above.

First, as shown in FIG. 3A, a buffer layer 120 is formed on the substrate 110, an active layer 130 is patterned on the buffer layer 120, a gate insulating layer 140 and a gate electrode 150 are patterned on the active layer 130, an interlayer insulating layer 160 is formed on the gate electrode 150, and a first contact hole CH1 and a second contact hole CH2 are formed in the interlayer insulating layer 160 to expose the upper surfaces of one side and the other side of the active layer 130.

When the first contact hole (CH1) and the second contact hole (CH2) are formed, oxygen deficiency can occur on the upper surface of one side and the upper surface of the other side of the active layer 130.

Next, as shown in FIG. 3B, the first contact layer 170a is patterned on the upper surface of one side of the active layer 130 exposed by the first contact hole CH1, and the second contact layer 170b is patterned on the upper surface of the other side of the active layer 130 exposed by the second contact hole CH2.

Oxygen included in the first contact layer 170a may fill a place in the upper surface of one side of the active layer 130 from which oxygen has escaped, and oxygen included in the second contact layer 170b may fill a place in the upper surface of the other side of the active layer 130 from which oxygen has escaped.

In this case, the contact layers 170a and 170b may be formed to have a thickness D of 30 Å to 100 Å.

When the interlayer insulating layer 160 is not made of an oxide such as silicon oxide but is made of a nitride such as silicon nitride, the metal oxide constituting the contact layers 170a and 170b may not be deposited on the interlayer insulating layer 160 and may be deposited only on the upper surface of the active layer 130 in the contact holes CH1 and CH2. Therefore, when the interlayer insulating layer 160 is made of nitride, selective deposition is possible without the need for a separate patterning process for forming the contact holes 170a and 170b.

The first contact layer 170a and the second contact layer 170b may be formed through atomic layer deposition (ALD) in which a process cycle including supplying a source gas containing metal, purging the source gas, supplying a reactive gas containing oxygen, and purging the reactive gas is repeated multiple times.

The supplying of the source gas may include at least one of supplying a gas containing zinc (Zn), supplying a gas containing indium (In), supplying a gas containing gallium (Ga), supplying a gas containing indium (In) and zinc (Zn), supplying a gas containing indium (In) and gallium (Ga), supplying a gas containing zinc (Zn) and gallium (Ga), and supplying a gas containing indium (In), zinc (Zn), and gallium (Ga).

For example, the first contact layer 170a and the second contact layer 170b may include zinc oxide (ZnO) formed by repeating multiple times a process cycle including supplying a source gas containing zinc (Zn) into the chamber, purging the source material gas, supplying a reactive gas containing oxygen into the chamber, and purging the reactive gas.

Alternatively, the first contact layer 170a and the second contact layer 170b may be formed of indium oxide (InO) formed by repeating multiple times a process cycle including supplying a source gas containing indium (In) into the chamber, purging the source gas, supplying a reactive gas containing oxygen into the chamber, and purging the reactive gas.

Alternatively, the first contact layer 170a and the second contact layer 170b may be formed of gallium oxide (GaO) formed by repeating multiple times a process cycle including supplying a source gas containing gallium (Ga) into the chamber, purging the source gas, supplying a reactive gas containing oxygen into the chamber above, and purging the reactive gas.

Alternatively, the first contact layer 170a and the second contact layer 170b may be formed of indium-zinc oxide (IZO) formed by repeating multiple times a process cycle including supplying a source gas containing indium (In) and zinc (Zn) into the chamber, purging the source gas, supplying a reactive gas containing oxygen into the chamber above, and purging the reactive gas.

Alternatively, the first contact layer 170a and the second contact layer 170b may consist of indium-zinc oxide (IZO) formed by repeating multiple times a process cycle including supplying a first source gas containing indium (In) into the chamber, purging the first source gas, supplying a first reactive gas containing oxygen into the chamber, purging the first reactive gas, supplying a second source gas containing zinc (Zn) into the chamber, purging the second source gas, supplying a second reactive gas containing oxygen into the chamber, and purging the second reactive gas.

Alternatively, the first contact layer 170a and the second contact layer 170b may be formed of indium-gallium oxide (IGO) formed by repeating multiple times a process cycle including supplying a source gas containing indium (In) and gallium (Ga) into the chamber, purging the source gas, supplying a reactive gas containing oxygen into the chamber above, and purging the reactive gas.

Alternatively, the first contact layer 170a and the second contact layer 170b may consist of indium-gallium oxide (IGO) formed by repeating multiple times a process cycle including supplying a first source gas containing indium (In) into the chamber, purging the first source gas, supplying a first reactive gas containing oxygen into the chamber, purging the first reactive gas, supplying a second source gas containing gallium (Ga) into the chamber, purging the second source gas, supplying a second reactive gas containing oxygen into the chamber, and purging the second reactive gas.

Alternatively, the first contact layer 170a and the second contact layer 170b may be formed of gallium-zinc oxide (GZO) formed by repeating multiple times a process cycle including supplying a source gas containing gallium (Ga) and zinc (Zn) into the chamber, purging the source gas, supplying a reactive gas containing oxygen into the chamber above, and purging the reactive gas.

Alternatively, the first contact layer 170a and the second contact layer 170b may consist of gallium-zinc oxide (GZO) formed by repeating multiple times a process cycle including supplying a first source gas containing gallium (Ga) into the chamber, purging the first source gas, supplying a first reactive gas containing oxygen into the chamber, purging the first reactive gas, supplying a second source gas containing zinc (Zn) into the chamber, purging the second source gas, supplying a second reactive gas containing oxygen into the chamber, and purging the second reactive gas.

Alternatively, the first contact layer 170a and the second contact layer 170b may consist of indium-gallium-zinc oxide (IGZO) formed by repeating multiple times a process cycle including supplying a first source gas containing gallium (Ga) into the chamber, purging the first source gas, supplying a first reactive gas containing oxygen into the chamber, purging the first reactive gas, supplying a second source gas containing indium (In) and zinc (Zn) into the chamber, purging the second source gas, supplying a second reactive gas containing oxygen into the chamber, and purging the second reactive gas.

Alternatively, the first contact layer 170a and the second contact layer 170b may consist of indium-gallium-zinc oxide (IGZO) formed by repeating multiple times a process cycle including supplying a first source gas containing indium (In) into the chamber, purging the first source gas, supplying a first reactive gas containing oxygen into the chamber, purging the first reactive gas, supplying a second source gas containing gallium (Ga) and zinc (Zn) into the chamber, purging the second source gas, supplying a second reactive gas containing oxygen into the chamber, and purging the second reactive gas.

Alternatively, the first contact layer 170a and the second contact layer 170b may consist of indium-gallium-zinc oxide (IGZO) formed by repeating multiple times a process cycle including supplying a first source gas containing zinc (Zn) into the chamber, purging the first source gas, supplying a first reactive gas containing oxygen into the chamber, purging the first reactive gas, supplying a second source gas containing gallium (Ga) and indium (In) into the chamber, purging the second source gas, supplying a second reactive gas containing oxygen into the chamber, and purging the second reactive gas.

Alternatively, the first contact layer 170a and the second contact layer 170b may consist of indium-gallium-zinc oxide (IGZO) formed by repeating multiple times a process cycle including supplying a first source gas containing zinc (Zn) into the chamber, purging the first source gas, supplying a first reactive gas containing oxygen into the chamber, purging the first reactive gas, supplying a second source gas containing gallium (Ga) into the chamber, purging the second source gas, supplying a second reactive gas containing oxygen into the chamber, purging the second reactive gas, supplying a third source gas containing indium (In) into the chamber, purging the third source gas, supplying a third reactive gas containing oxygen into the chamber, and purging the third reactive gas. There is no particular order between the supply of the first to third source gases.

Next, as shown in FIG. 3C, a source electrode 180a is formed on the first contact layer 170a, and a drain electrode 180b is formed on the second contact layer 170b.

The source electrode 180a extends into the first contact hole CH1 to be in contact with the first contact layer 170a, and the drain electrode 180b extends into the second contact hole CH2 to be in contact with the second contact layer 170b.

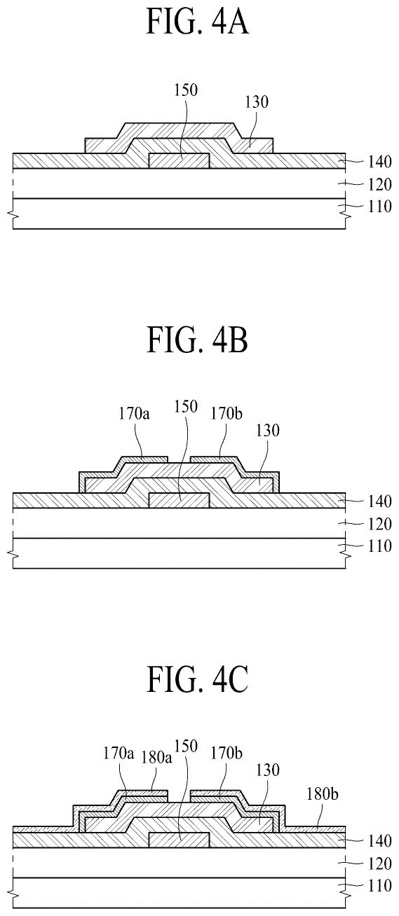

FIGS. 4a to 4c are cross-sectional views of a schematic manufacturing process of a thin film transistor in accordance with another embodiment of this invention, and are related to a manufacturing process of the thin film transistor according to FIG. 2 described above.

First, as shown in FIG. 4A, a buffer layer 120 is formed on the substrate 110, a gate electrode 150 is patterned on the buffer layer 120, a gate insulating layer 140 is formed on the gate electrode 150, and an active layer 130 is patterned on the gate insulating layer 140.

Next, as shown in FIG. 4B, a first contact layer 170a is patterned on an upper surface of one side of the active layer 130, and a second contact layer 170b is patterned on an upper surface of the other side of the active layer 130.

A method of forming the first contact layer 170a and the second contact layer 170b is the same as described above, and thus a repeated description thereof will be omitted.

Next, as shown in FIG. 4C, a source electrode 180a is patterned on the first contact layer 170a, and a drain electrode 180b is patterned on the second contact layer 170b.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A thin film transistor comprising:
a gate electrode;
an active layer spaced apart from the gate electrode;
a source electrode provided on one side of the active layer;
a drain electrode provided on the other side of the active layer; and
a contact layer provided at least one of an area between the active layer and the source electrode and an area between the active layer and the drain electrode,
wherein the contact layer comprises a first metal oxide of at least one selected from Zn, In, and Ga.

2. The thin film transistor of claim 1, wherein the contact layer includes a first contact layer provided between the active layer and the source electrode, and a second contact layer provided between the active layer and the drain electrode.

3. The thin film transistor of claim 1, wherein the active layer includes a second metal oxide, and the second metal oxide included in the active layer and the first metal oxide included in the contact layer are different from each other.

4. The thin film transistor of claim 3, wherein metal included in the first metal oxide is different from metal included in the second metal oxide.

5. The thin film transistor of claim 3, wherein a composition ratio of metal and oxygen included in the first metal oxide is different from a composition ratio of metal and oxygen included in the second metal oxide.

6. The thin film transistor of claim 3, wherein oxygen content included in the first metal oxide is less than oxygen content included in the second metal oxide.

7. The thin film transistor of claim 1, wherein the contact layer has a thickness in the range of 30 Å to 100 Å.

8. The thin film transistor of claim 1, wherein a pattern of the contact layer is different from a pattern of the active layer.

9. The thin film transistor of claim 1, further comprising an interlayer insulating layer provided between the active layer and the source electrode,
wherein the interlayer insulating layer is provided with a contact hole for exposing the source electrode, and the contact layer is provided in the contact hole.

10. The thin film transistor of claim 1, further comprising a gate insulating layer provided between the gate electrode and the active layer,
wherein the source electrode extends from an upper surface of the contact layer to an upper surface of the gate insulating layer.

11. A method of manufacturing a thin film transistor comprising:
forming an active layer on a substrate;
forming a gate insulating film and a gate electrode on the active layer;
forming an interlayer insulating layer on the gate electrode;
forming a contact hole in the interlayer insulating layer to expose the active layer through the contact hole;
forming a contact layer containing a first metal oxide of at least one selected from Zn, In, and Ga on an exposed upper surface of the active layer within the contact hole; and
forming a source electrode or a drain electrode on the contact layer.

12. The method of manufacturing a thin film transistor of claim 11, wherein the interlayer insulating layer is made of nitride, and the contact layer is formed by a selective deposition process without a patterning process.

13. A method of manufacturing a thin film transistor comprising:
forming a gate electrode on a substrate;
forming a gate insulating film on the gate electrode;
forming an active layer on the gate insulating film;
forming a contact layer containing a first metal oxide of at least one selected from Zn, In, and Ga on an upper surface of the active layer; and
forming a source electrode or a drain electrode on the contact layer.

14. The method of manufacturing a thin film transistor of claim 13,
wherein the active layer includes a second metal oxide, and the second metal oxide included in the active layer and the first metal oxide included in the contact layer are different from each other.

15. The method of manufacturing a thin film transistor of claim 14,
wherein metal included in the first metal oxide is different from metal included in the second metal oxide.

16. The method of manufacturing a thin film transistor of claim 14,
wherein a composition ratio of metal and oxygen included in the first metal oxide is different from a composition ratio of metal and oxygen included in the second metal oxide.

17. The method of manufacturing a thin film transistor of claim 14,
wherein oxygen content included in the first metal oxide is less than oxygen content included in the second metal oxide.

18. The method of manufacturing a thin film transistor of claim 14,
wherein the contact layer has a thickness in the range of 30 Å to 100 Å.
